(19) United States
(12) Patent Application Publication
(10) Pub. No.: US 2006/0185822 A1
(43) Pub. Date: Aug. 24, 2006

(54) System and method for thermal management using distributed synthetic jet actuators

(75) Inventors: Ari Glezer, Atlanta, GA (US); Raghavendran Mahalingam, Decatur, GA (US)

Correspondence Address: FORTKORT & HOUSTON P.C., 9442 N. CAPITAL OF TEXAS HIGHWAY, ARBORETUM PLAZA ONE, SUITE 500, AUSTIN, TX, 78759, US

(73) Assignee: GEORGIA TECH RESEARCH CORPORATION

(21) Appl. No.: 11/406,924

(22) Filed: Apr. 18, 2006

Related U.S. Application Data
(63) Continuation of application No. 11/325,239, filed on Jan. 4, 2006.

(30) Foreign Application Priority Data
Jul. 7, 2004 (WO) PCT/US04/21706

(51) Int. Cl. H05K 7/20

(52) U.S. Cl. 165/80.3; 165/121; 361/697

(57) ABSTRACT

One embodiment of the device comprises a device for thermal management. More particularly, one embodiment comprises a synthetic jet actuator (60) and a tube (61). The synthetic jet actuator (60), though not required, typically comprises a housing (47) defining an internal chamber (45) and having an orifice (46) in a wall (44) of the housing (47). The synthetic jet actuator (60) typically also comprises a flexible diaphragm (42) forming a portion of the housing (47). The tube (61) of this exemplary embodiment typically comprises a proximal end (64) and a distal end (65), the proximal end (64) being positioned adjacent to the synthetic jet actuator (60). In this embodiment, operation of the synthetic jet actuator (60) causes a synthetic jet stream (52) to form at the distal end (65) of the tube (61).

### TECHNICAL FIELD

The present invention is generally related to thermal management technology and, more particularly, is related to a system and method for cooling heat-producing bodies or components using distributed synthetic jet actuators.

### BACKGROUND OF THE INVENTION

Cooling of heat-producing bodies is a concern in many different technologies. Particularly in microprocessors, the rise in heat dissipation levels accompanied by a shrinking thermal budget has resulted in the need for new cooling solutions beyond conventional thermal management techniques. Moreover, there is a greatly increased demand for effective thermal management strategies to be used within small handheld devices, such as portable digital assistants (PDA's), mobile phones, portable CD players, and similar consumer products. Indeed, thermal management is a major challenge in the design and packaging of state-of-the-art integrated circuits in single-chip and multi-chip modules.

Traditionally, the need for cooling large microelectronic devices has been met by using forced convection air cooling techniques. Forced convection can be implemented either with or without heat sinks. Conventionally, fans are employed to provide either global cooling or local cooling.

Fans are capable of supplying ample volume flow rate, but there are several distinct disadvantages to using a fan. Fans are relatively inefficient in terms of the heat removed for a given volume flow rate. In addition, the use of fans to globally or locally cool a heated environment often results in electromagnetic interference and noise generated by the magnetic-based fan motor. Use of a fan also requires a relatively large number of moving parts in order to have any success in cooling a heated body or microelectronic component. For this or other reasons, fans may be hindered by long-term reliability.

Mobile applications introduce the added complication of space constraints that might be difficult to achieve with fans, while at the same time increased thermal management requirements have necessitated larger fans driving higher flow rates. Since the power dissipation requirements have necessitated placing fans directly on the heat sink in some instances, the associated noise levels due to the flow-structure interaction have become an additional concern.

In some instances, as in handhelds like portable digital assistants (“PDAs”), cell phones, etc., the need for thermal management has been met by employing a strategy of spreading the heat produced through the use of heat spreaders to the outer shell of the handheld. Subsequently, the heat generated is dissipated though the outer shell, or skin, of the device via natural convection.

While these approaches are common, they offer certain drawbacks that will be exacerbated as new products that produce even more heat are developed. The difficulty with the heat spreading strategy is simply that it is often ineffective at removing adequate quantities of heat. Additionally, the heat dissipated may result in raising the temperature of the casing of the handheld device, which is not desirable from a consumer use ergonomic standpoint.

In an effort to remedy some of the limitations of previous cooling techniques, the use of synthetic or “zero-net-mass-flux” jet actuators in thermal management has been explored. For example, U.S. Pat. No. 6,123,145 discusses the use of synthetic jet actuators for use in cooling. U.S. Pat. No. 6,123,145 is hereby incorporated by reference in its entirety, as if fully set forth herein. Unlike conventional jets, synthetic jet actuators require no mass addition to the system, and thus provide a compact way of efficiently directing airflow across a heated surface. Because the jet streams are generated entirely from the ambient fluid, they can be conveniently integrated without the need for complex plumbing.

As a further example of the development of thermal management techniques with synthetic jet actuators, Glezer and Mahalingam developed an apparatus and device for channel cooling. This apparatus and method is described in U.S. Pat. No. 6,588,497, which is hereby incorporated by reference in its entirety, as if fully set forth herein.

While the techniques described in the afore-mentioned U.S. patents solve some of the limitations in the industry, there is an ever-increasing need for improving even the aforementioned techniques. For example, there is a need for a more effective, efficient, or compact synthetic jet actuator. It is desirable to have a more compact cooling device. On the other hand, there is also a need to distribute the cooling flow to far-reaching parts of a heated environment.

Thus, a heretoforeunaddressed need exists in the industry to address the aforementioned deficiencies and inadequacies.

### SUMMARY OF THE INVENTION

Embodiments of the present invention provide a device for thermal management in various environments. More specifically, the present embodiments include devices for cooling an area or device through the use of synthetic jet actuators in a distributed cooling apparatus.

Briefly described, in architecture, one embodiment of the device, among others, can be implemented as a device for thermal management comprising a synthetic jet actuator and a channel. The channel of this exemplary embodiment typically comprises a proximal end and a distal end, the proximal end being positioned adjacent to the synthetic jet actuator. Operation of the synthetic jet actuator preferably causes a synthetic jet stream to form at the distal end of the channel. Of course, the synthetic jet stream may also form at the proximal end of the channel.

The synthetic jet actuator of this or other exemplary embodiments, though not required, may comprise a housing defining an internal chamber and having at least one orifice in a wall of the housing. The synthetic jet actuator of this embodiment also preferably comprises a device for changing the volume of the internal chamber, wherein the volume changing device is preferably positioned adjacent to the housing. In some embodiments, the device for changing the volume may actually make up a portion of the synthetic jet actuator housing. For example, the volume changing device of some exemplary embodiments comprises a flexible diaphragm forming a portion of the synthetic jet actuator housing.

In some exemplary embodiments, the channel is comprised of one or more tubes connected to an external surface of a wall of the synthetic jet actuator housing. In these exemplary embodiments the tube (or tubes) typically encloses at least a portion of a synthetic jet actuator orifice.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1A is a schematic cross-sectional side view of a first exemplary embodiment zero net mass flux synthetic jet actuator with a control system.

FIG. 1B is a schematic cross-sectional side view of the synthetic jet actuator of FIG. 1A depicting the jet as the control system causes the diaphragm to travel inward, toward the orifice.

FIG. 1C is a schematic cross-sectional side view of the synthetic jet actuator of FIG. 1A depicting the jet as the control system causes the diaphragm to travel outward, away from the orifice.

FIG. 2 is a cross-sectional side view of a second exemplary embodiment of a synthetic jet actuator.

FIG. 3 is a bottom view of the second exemplary embodiment of a synthetic jet actuator of FIG. 2.

FIG. 4A is a cross-sectional side view of a distributed cooling apparatus.

FIG. 4B is a cross-sectional side view of the tube used in the distributed cooling apparatus of FIG. 4A as the tube withdraws fluid from an ambient.

FIG. 4C is a cross-sectional side view of the tube used in the distributed cooling apparatus of FIG. 4A as the tube creates a synthetic jet stream of fluid at an exit end of the tube.

FIG. 5 is a cross-sectional top view of a distributed cooling apparatus for directing fluid flow to different areas of a heated environment.

FIG. 6 is a three-dimensional view of a multiple actuator distributed cooling apparatus.

FIG. 7 is a cross-sectional side view of the multiple actuator distributed cooling apparatus of FIG. 6, focussing on one of the “plenums” of the multiple actuator distributed cooling apparatus.

FIG. 8 is a cross-sectional side view of the multiple actuator distributed cooling apparatus of FIG. 6, focussing on one of the “plenums” of the apparatus, where actuators have been installed into the “plenum.”

FIG. 9 is a three-dimensional, cut-away view of the multiple actuator distributed cooling apparatus of FIG. 6.

FIG. 10 is a cut-away schematic rear view of the multiple actuator distributed cooling apparatus of FIG. 6.

FIG. 11A is a side view of the multiple actuator distributed cooling apparatus of FIG. 6 implemented into a cooling system.

FIG. 11B is a front view of the multiple actuator distributed cooling apparatus of FIG. 6 implemented into a cooling system.

FIG. 12A is a side view of a prior art cooling system.

FIG. 12B is a side view of the cooling system of FIG. 12A wherein the multiple actuator distributed cooling apparatus of FIG. 6 has been implemented into the cooling system.

### DETAILED DESCRIPTION OF THE PREFERRED EMBODIMENT

I. Synthetic Jet Actuators

A. Basic Design of a Typical Synthetic Jet Actuator

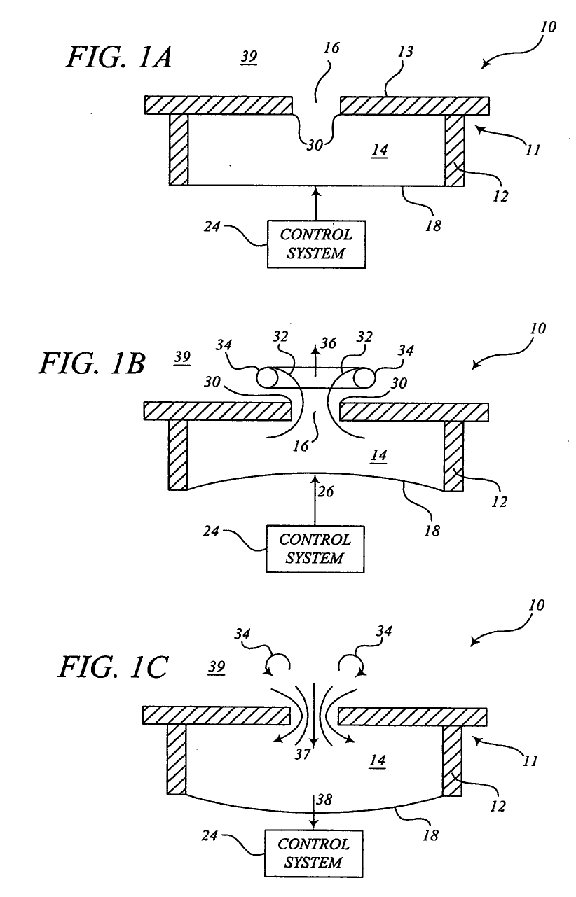

FIG. 1A depicts an example of a synthetic jet actuator 10 comprising a housing 11 defining and enclosing an internal chamber 14. The housing 11 and chamber 14 can take virtually any geometric configuration, but for purposes of discussion and understanding, the housing 11 is shown in cross-section in FIG. 1A to have a rigid side wall 12, a rigid front wall 13, and a rear diaphragm 18 that is flexible to an extent to permit movement of the diaphragm 18 inwardly and outwardly relative to the chamber 14. The front wall 13 has an orifice 16 of any geometric shape. The orifice diametrically opposes the rear diaphragm 18 and connects the internal chamber 14 to an external environment having ambient fluid 39.

The flexible diaphragm 18 may be controlled to move by any suitable control system 24. For example, the diaphragm 18 may be equipped with a metal layer, and a metal electrode may be disposed adjacent to, but spaced from, the metal layer so that the diaphragm 18 can be moved via an electrical bias imposed between the electrode and the metal layer. Moreover, the generation of the electrical bias can be controlled by any suitable device, for example but not limited to, a computer, logic processor, or signal generator. The control system 24 can cause the diaphragm 18 to move periodically, or modulate in time-harmonic motion, and force fluid in and out of the orifice 16.

The operation of the example synthetic jet actuator 10 will now be described with reference to FIGS. 1B and 1C. FIG. 1B depicts the synthetic jet actuator 10 as the diaphragm 18 is controlled to move inward into the chamber 14, as depicted by arrow 26. The chamber 14 has its volume decreased and fluid is ejected through the orifice 16. As the fluid exits the chamber 14 through the orifice 16, the flow separates at sharp orifice edges 30 and creates vortex sheets 32 which roll into vortices 34 and begin to move away from the orifice edges 30 in the direction indicated by arrow 36.

FIG. 1C depicts the synthetic jet actuator 10 as the diaphragm 18 is controlled to move outward with respect to the chamber 14, as depicted by arrow 38. The chamber 14 has its volume increased and ambient fluid 39 rushes into the chamber 14 as depicted by the set of arrows 37. The diaphragm 18 is controlled by the control system 24 so that when the diaphragm 18 moves away from the chamber 14, the vortices 34 are already removed from the orifice edges 30 and thus are not affected by the ambient fluid 39 being drawn into the chamber 14. Meanwhile, a jet of ambient fluid 39 is synthesized by the vortices 34 creating strong entrainment of ambient fluid drawn from large distances away from the orifice 16.

B. Synthetic Jet Actuator Having a Hybrid Piezoelectric Actuator

As explained above, the diaphragm 18 of the synthetic jet actuator 10 of the first exemplary embodiment comprises electrical actuation consisting of a metal layer and a metal electrode driven at a specific excitation frequency. This electrical stimulation causes the diaphragm 18 of the synthetic jet actuator 10 to oscillate, thereby modifying the internal volume of the chamber 14 of the synthetic jet actuator 10.

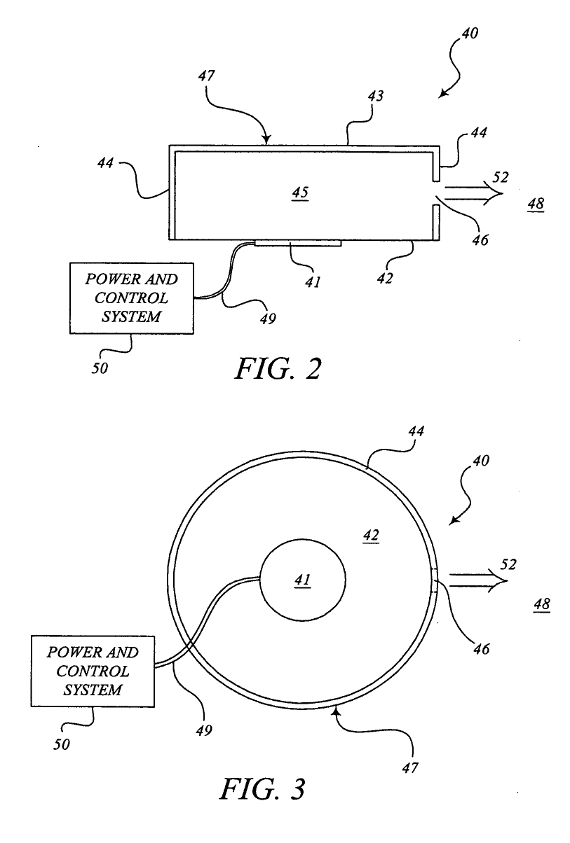

Alternatively, as depicted in FIG. 2, a synthetic jet actuator 40 could comprise a housing 47 defining a chamber 45. The chamber volume could be altered by causing a flexible diaphragm 42 to move in time-harmonic motion due to the excitation of the diaphragm 42 by a piezoelectric actuator 41. FIG. 2 is a cut-away side view of a synthetic jet actuator 40 having a housing 47 defined by a relatively-rigid circular top wall 43, a relatively-rigid circular cylindrical side wall 44, and a flexible diaphragm 42 forming a bottom wall of the actuator 40. As depicted in the figure, the side wall connects the top wall 43 to the diaphragm 42. Preferably, the side wall 44 and the top wall 43 are manufactured from a single piece of rigid material, such as plastic. It would, of course, also be possible to construct the walls 43, 44 from a metallic material, or other suitably-rigid material. Additionally, the material forming the synthetic jet actuator 40 does not necessarily have to be rigid. The material could have some flexibility. One with ordinary skill in the art would readily understand the appropriate material for the synthetic jet actuator 40 based on a particular implementation.

As noted above, the top wall 43, the flexible diaphragm 42, and the side wall 44 form the housing 47 of a synthetic jet actuator 40 and define a chamber 45 having a volume. The housing 47 of this embodiment 40 comprises the shape of a cylindrical element. This configuration is not required, and the particular configuration has been selected in order to drive home the point that a synthetic jet actuator 40 can take almost any overall shape.

In this embodiment of a synthetic jet actuator 40, an orifice 46 is formed in a portion of the side wall 44. The orifice 46 fluidically connects the chamber 45 with an ambient fluid 48. The particular size and shape of the orifice 46 is not critical to the present exemplary embodiment 40. By way of example, the orifice 46 could be in the shape of a circular opening, or of a horizontal or vertical slot in the side wall 44.

FIG. 3 is a plan view of the second exemplary embodiment of a synthetic jet actuator 40, more specifically depicting the piezoelectric actuator 41 and flexible diaphragm 42. In other words, FIG. 3 can be thought of as a view of the synthetic jet actuator 40 from the underside, or “bottom” of the actuator 40. As can be seen from the figure, the diaphragm 42 is attached to the side wall 44. Preferably, the attachment of the diaphragm 42 to the side wall 44 is accomplished by an adhesive appropriate to the materials used to construct the diaphragm 42 and the side wall 44. Alternatively, the diaphragm 42 could be attached to the side wall 44 by another attachment mechanism or device. The method of attachment is not critical to the present exemplary embodiment 40. It is preferred, however, that the selected method of attachment result in a seal between the side wall 44 and the diaphragm 42.

The diaphragm 42 is preferably constructed of an elastomer or polymer material. An elastomer or polymer diaphragm 42 is not required in the present embodiment 40; however, a diaphragm constructed from these materials is preferred. Conventionally, piezoelectric actuators are comprised of a metal diaphragm coupled with a piezoelectric disc. However, it may be advantageous in certain implementations to use a polymeric (like plastic) or elastomeric (like rubber) material for a diaphragm of the piezoelectric actuator. Alternatively, a polymeric or elastomeric diaphragm could be used in combination with a metal diaphragm to produce a hybrid diaphragm.

An elastomer or polymer can be constructed from a number of specific materials, such as polyisoprene, polyisobutylene, polybutadiene, and/or polyurethanes. For the present embodiment 40, a diaphragm 42 constructed of an elastomer or polymer material is chosen due to its ability to be stretched and yet bounce back into its original shape without permanent deformation.

There are at least two advantages to such a modified actuator construction. First, the use of an elastomer or polymer diaphragm generally reduces the natural resonant frequency of the actuator, enabling its preferred use at low frequencies (for example, <200 Hz). This renders the actuator operation relatively soundless. Second, such a construction generally has superior reliability when compared to metal diaphragms that tend to produce larger stresses in the piezoelectric material and the adhesive that typically attaches the piezoelectric material to the metal.

As noted above, a piezoelectric actuator 41 is attached to the elastomer or polymer diaphragm 42. The piezoelectric actuator 41 is preferably mounted to the diaphragm 42 by an appropriate adhesive. The piezoelectric actuator 41 is supplied power by electrical wiring 49. The electrical wiring 49 will not only supply power to the piezoelectric actuator 41, but will also control operation of the actuator 41. Specifically, the wiring 49 connects the piezoelectric actuator with a power supply and control system 50 that is preferably separate from the housing 47 of the synthetic jet actuator 40. Of course, in certain embodiments, the power supply and control system 50 may be mounted on, or even in, the housing 47 of the synthetic jet actuator 40.

The power supply and control system causes the piezoelectric actuator 41 to vibrate. The vibration of the piezoelectric actuator 41 causes the diaphragm 42 to oscillate in time-harmonic motion. The piezoelectric actuator 41 is preferably caused to vibrate at the resonant frequency of the diaphragm 42. Of course, the magnitude and frequency of the diaphragm oscillation can be controlled by causing the piezoelectric actuator to operate at different frequencies. One with ordinary skill in the art will readily be able to adjust the vibration of the piezoelectric actuator 41 in order to yield the desired frequency and amplitude of oscillation of the diaphragm 42.

As noted above with respect to the first exemplary embodiment 10, the oscillation of the diaphragm 42 in the second exemplary embodiment 40 causes a synthetic jet stream 52 of fluid to form at the orifice 46 of the actuator 40. As the diaphragm 42 moves inward with respect to the chamber 45, the chamber 45 has its volume decreased and fluid is ejected through the orifice 46. As the fluid exits the chamber 45 through the orifice 46, the flow separates at orifice edges and creates vortex sheets which roll up into vortices and to move away from the orifice 46. These vortices entrain the ambient fluid 48 and use this fluid to form a synthetic jet stream 52.

Similar to the operation of the first exemplary synthetic jet actuator 10, when the diaphragm 42 is caused to move outward with respect to the chamber 45, the chamber 45 has its volume increased. This increase in volume causes a pressure gradient to form at the orifice 46 and ambient fluid 48 rushes into the chamber 45. Then, as the diaphragm 42 oscillates back into the chamber 45, the fluid in the chamber 45 is expelled, forming a synthetic jet stream 52 as described above.

III. Distributed Cooling Apparatus

A. First Example: Single Actuator Device

The synthetic jet actuators 10, 40 described above can be used in a number of different embodiments. However, one specific adaptation of the synthetic jet actuators 10, 40 is for what may be referred to as distributed cooling applications. A distributed cooling application is a situation that may call for a single synthetic jet actuator to provide a cooling synthetic jet stream to multiple locations. Alternatively, a distributed cooling application may call for a synthetic jet actuator to supply cooling fluid flow to a single location that is somewhat remote from the location of the actuator. Although not limiting examples, these two examples are common distributed cooling applications.

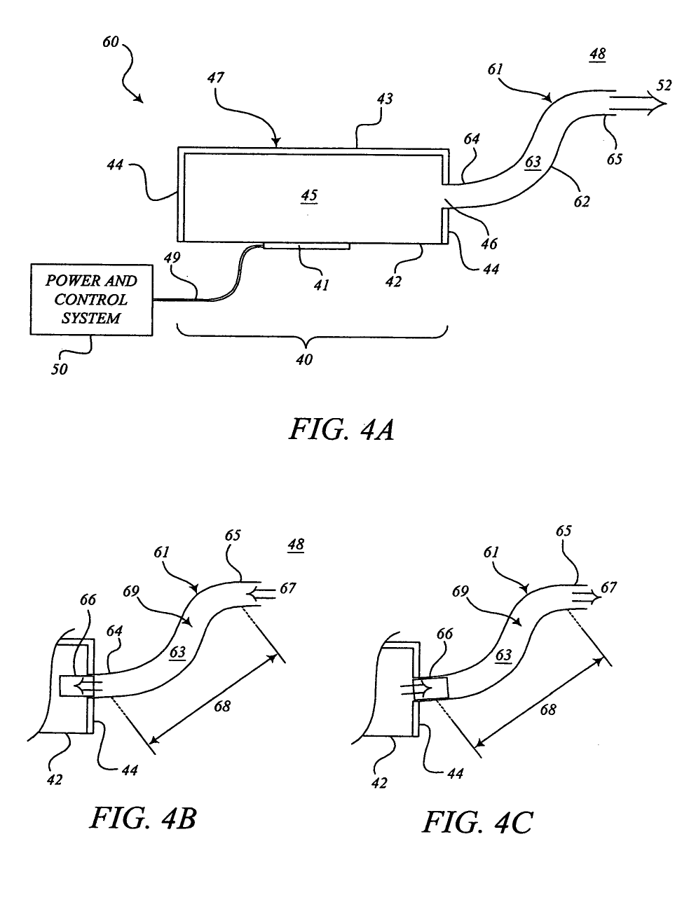

FIG. 4A depicts one embodiment of a distributed cooling synthetic jet actuator 60. For ease of explanation, the exemplary embodiment of a distributed cooling synthetic jet actuator 60 has been designed as a modified form of the second exemplary embodiment 40. As such, the distributed cooling synthetic jet actuator 60 comprises a housing 47 defining an internal chamber 45. The housing 47 and chamber 45 can take virtually any geometric configuration, but for purposes of discussion and understanding, the housing 47 is shown in cross-section in FIG. 4A to have a rigid side wall 44, a rigid top wall 43, and a diaphragm 42 that is flexible to an extent to permit movement of the diaphragm 42 inwardly and outwardly relative to the chamber 45. A portion of the side wall 44 forms an orifice 46. As above, the orifice 46 can have any geometric shape.

As with the exemplary embodiment 40 above, the distributed cooling synthetic jet actuator 60 also comprises a power supply and control system 50 connected to a piezoelectric actuator 41 on the diaphragm 42 by electrical wiring 49. As above, the power supply and control system 50 may be remote from the actuator 60, or may be attached to the housing 47 or in the housing 47 for example.

The exemplary distributed cooling apparatus 60 further comprises a channel, or a tube, 61. The tube 61 may be of similar cross-sectional shape as that of the orifice 46. However, it may also be desirable to have the cross-sectional shape of the tube 61 very different from the shape of the orifice 46. For example, the use of a different cross-sectional shape may permit more effective directing of any flow emitting from the tube 61. The tube 61 is formed of a preferably rigid shell 62 enclosing an inner area 63. The tube 61 further comprises a proximal, or attachment end 64 and a distal, or open end 65. The tube 61 is preferably constructed from a plastic material such that the tube 61 will be relatively-rigid, but still lightweight. Alternatively, the tubing 61 could be constructed from a flexible material having the ability to be formed into a shape and hold that shape. In FIG. 4A, the tube 61 is formed into a generally serpentine shape. The shape of the tube 61 is not important to the principles of the present invention, and the particular shape depicted has been chosen only to illustrate the principles of the present exemplary embodiment 60.

As shown in the figure, the tube 61 is preferably attached to the side wall 44 of the synthetic jet actuator 60 such that the actuator orifice is fluidically coupled to the interior region 63 of the tubing 61. In the preferred configuration, the tubing 61 has an internal diameter equal to or greater than the diameter of the orifice 46. Thus, the orifice 46 does not communicate directly with the ambient environment 48, or in other words, the tube 61 completely covers the orifice 46. Although the tube 61 is referred to as “attached” to the side wall 44, it should be understood that the housing 47 and tube 61 can be created from a single piece of material.

As will be explained in more detail below, during operation, vortices form at the edges of the tubing exit end 65. These vortices roll up and move away from the exit of the tube 61. These vortices entrain ambient fluid 48 forming a fluidic jet 52 at the exit 65 of the tube 61. In essence, the use of tubing 61 permits a jet of fluid 52 to eject from the tubing 61, away from the actuator itself. Basically, the synthetic jet of fluid that would be emitted from the orifice 46 of the synthetic jet actuator, if no tube 61 was present, is emitted instead from the exit end 65 of the tube 61. This feature of the present embodiment 60 permits a designer of a cooling system to position the synthetic jet actuator 40 at any convenient location, but still direct the fluid flow 52 to a relatively-distant location by simply directing the tube 61 to this desired location.

For example, the actuator 40 could be positioned a distance away from the area to be cooled, such as in a centralized location. The tubing 61 could be shaped to direct flow through the fins of a heat sink. The fact that the synthetic jet actuator is not near the heat sink will generally increase the flow through the heat sink fins. Indeed, if the actuator is positioned at the entrance of a fin channel, the flow through the fin channel may be impeded by the presence of the actuator housing. This is not an issue with distributed cooling.

As noted above, the tubing 61 could either be pre-formed or flexible. If flexible, the designer could place the device 40 and then shape tube 61 as desired. This may be very beneficial for retrofit applications. However, in the most common embodiment, the tube 61 will be relatively-rigid such that the design of the overall cooling system can be fine-tuned prior to installation.

As noted above, the shape or dimensions of the tube 61 is not critical to the present exemplary embodiment 60. However, the length and/or shape of the tube 61 may affect the performance of the distributed cooling synthetic jet actuator 60. To better explain this point, resort should be made to the operation of the distributed cooling apparatus 60.

The operation of the synthetic jet actuator 40 in the distributed cooling apparatus 60 is similar to the operation of the synthetic jet actuator in the second exemplary embodiment described above. Specifically, the piezoelectric actuator 41 is caused to vibrate at an appropriate frequency, preferably the resonant frequency of the diaphragm 42. This vibration causes the diaphragm 42 to oscillate in time-harmonic motion. As the diaphragm 42 moves inward relative to the internal chamber 45, the volume of the chamber 45 is reduced, the pressure in the chamber 45 increases, creating a pressure gradient at the orifice 46, and fluid is ejected from the orifice 46 of the synthetic jet actuator 40. Because there is no ambient fluid to entrain at the orifice 46, the flow exiting the orifice 46 is generally pulsating in nature, generally reflecting the frequency of the diaphragm 42 driven by the piezoelectric actuator 41. This fluidic pulse moves into an interior region 63 of the tube 61 attached to the orifice 46. As the diaphragm 42 is moved outward with respect to the chamber 45, fluid is drawn into the synthetic jet actuator chamber 45 from the tube interior 63. Then, as the diaphragm 42 continues its time-harmonic oscillation and moves back into the chamber 45, fluid is again ejected from the chamber 45 into the tube interior 63.

FIGS. 4B and 4C depict the fluidic interaction within the interior 63 of the tube 61 during operation of the synthetic jet actuator 40 of the distributed cooling apparatus 60. When the fluid from the synthetic jet actuator chamber 45 enters the interior 63 of the tube 61, the entering fluid acts like a “virtual piston” 66. The pulse of fluid 66 entering the interior 63 of the tube 61 compresses the fluid in the tube interior 63, which in turn, causes fluid 67 to be expelled from the exit end 65 of the tube 61. When the diaphragm 42 moves outward from the synthetic jet actuator chamber 45, the “virtual piston” 66 moves out from the interior 63 of the tube 61, withdrawing fluid from the tube interior 63 into the chamber 45, thereby lowering the pressure in the tube 61. This lower pressure in the tube 61 creates a pressure gradient at the tube exit end 65, thereby drawing fluid from the ambient 48 into the tube 61. Again, the fluid at the tube attachment end 64 acts as a “virtual piston” 66, operating in time-harmonic oscillation.

The central portion 68 of the tube 61 acts like another synthetic jet actuator “chamber” 69 bounded by the walls 62 of the tube 61. The fluid at the orifice 46 of the synthetic jet actuator 40 bounds this “chamber” 69 and acts as a virtual piston 66 to this virtual synthetic jet actuator “chamber” 69. The fluid exiting and entering the orifice 46, acting as a piston 66, creates a flow of fluid 67 emitting from the exit end 65 of the tube 61. The fluid 67 exiting the tube 61 creates vortices at the exit 65 of the tube 61. These vortices roll up and move away from the tube exit 65. As the vortices form and move away, these vortices entrain the ambient fluid 48 in order to form a synthetic jet stream 67 at the exit 65 of the tube 61.

Depending on the length of the tube 61, the operation of the diaphragm 42 of the synthetic jet actuator 40 could be specifically tuned to create the virtual synthetic jet actuator in the tube 61. As is apparent from the discussion above, and as will be recognized by one of ordinary skill in the art, the operation of the diaphragm 42 should preferably be tuned such that the frequency of the air pulses 66 emitting from the orifice 46 of the synthetic jet actuator 40 are emitted at a resonant frequency of the tube 61. The tube 61, in essence, acts as a type of Helmholtz resonator and can be operated in like manner. The attachment end 64 of the tube 61 acts as the closed end of a typical Helmholtz resonator, and also as the exciting force to the resonator.

One of ordinary skill in the art can compute the resonant frequency of the tube 61 if the dimensions of the tube 61 are known. Then, the frequency and amplitude of the diaphragm 42 oscillation can be computed so that the pulses 66 emitted from the synthetic jet actuator 40 orifice 46 will excite the tube 61 at a resonant frequency. Of course, this could all be controlled automatically by an appropriate control system 50.

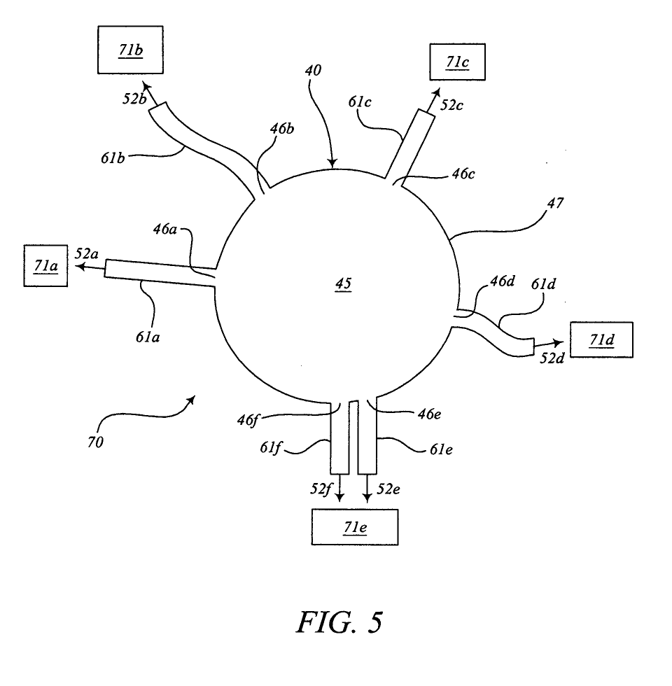

In another exemplary configuration of a distributed cooling synthetic jet actuator 70, the synthetic jet actuator 40 is configured to drive a number of tubes. Such a configuration is depicted in FIG. 5. FIG. 5 is a cut-away top view of a distributed cooling synthetic jet actuator. As shown, the synthetic jet actuator housing 47 of the actuator 70 preferably has multiple orifices 46a, 46b, 46c, 46d, 46e, 46f. On the exterior of the housing 47 are attached a number of tubes 61a, 61b, 61c, 61d, 61e, 61f such that these tubes 61a, 61b, 61c, 61d, 61e, 61f correspond to each of the orifices 46a, 46b, 46c, 46d, 46e, 46f. The tubes 61a, 61b, 61c, 61d, 61e, 61f could all be configured to direct fluid flow at the same area, or in the preferred application, are formed such as to direct synthetic jet streams 52a, 52b, 52c, 52d, 52e, 52f at separate heated areas or objects 71a, 71b, 71c, 71d, 71e.

In another embodiment of the distributed cooling apparatus, it may be desirable to have a ready means of attaching the synthetic jet actuator module to another surface. For example, if the distributed cooling apparatus will be used in a retrofit application, there may not be a ready method of attachment. In such a situation, it may be desirable to have the top wall 43 of the synthetic jet actuator 40 configured such as to readily adhere to a surface. The synthetic jet actuator 40 could be manufactured so as to “stick-on” to a surface. This can be accomplished by applying double sided tape, foam with adhesive on both sides, or the like.

B. Second Example: Multiple Actuator Device

In some implementations of a distributed cooling apparatus, it may be desirable to generate multiple synthetic jet streams. As noted above, a single synthetic jet actuator 40 may drive multiple tubes, and thereby generate multiple, distributed synthetic jet streams of fluid. This, of course, is not the only possible implementation of a multiple synthetic jet distributed cooling apparatus. Another exemplary embodiment may comprise multiple synthetic jet actuators driving multiple tubes, and thereby emitting multiple synthetic jet streams. The tubes of such an embodiment may be directed to different areas, different heat sink channels, or all to the same location.

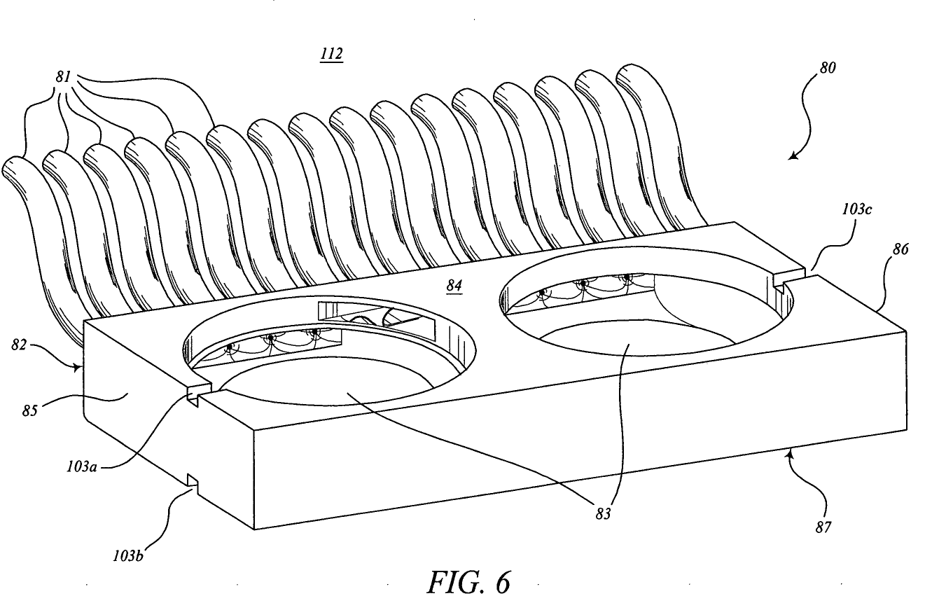

An exemplary embodiment of a multiple actuator distributed cooling apparatus 80 is depicted in FIG. 6. This apparatus 80 generally comprises a plurality of tubes 81 emerging from a generally rectangularly cubic housing 82. The housing 82 has two “plenums” 83 formed into the housing 82 such that these two plenums 83 descend from a top surface 84 of the housing 82. The two plenums 83 are spaced from the side walls 85, 86 of the housing 82, and do not preferably reach all the way to the bottom surface 87 of the housing 82.

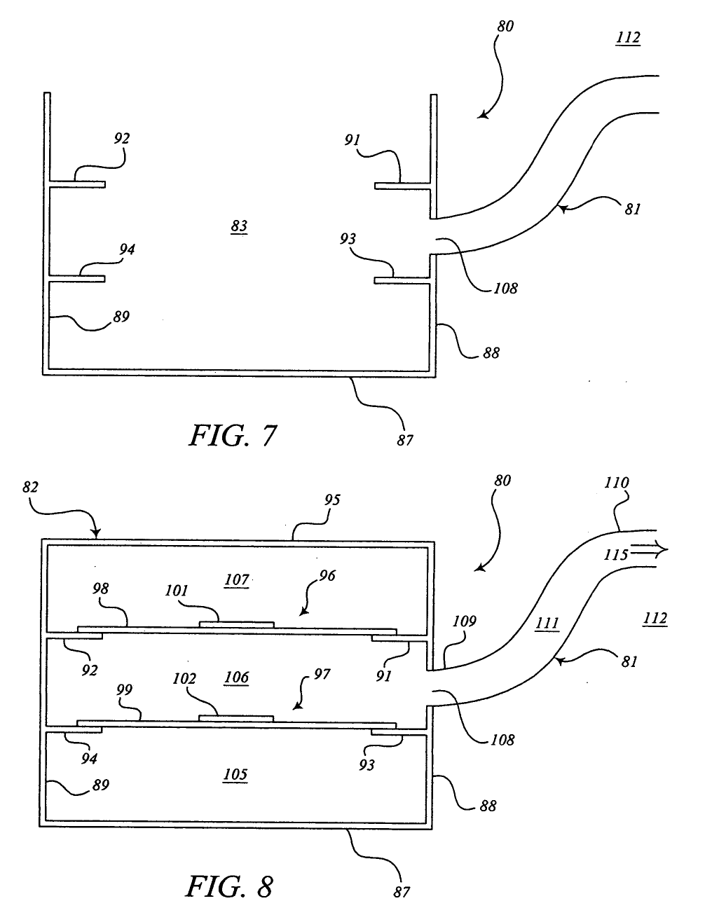

A cross-sectional side view of the multiple actuator distributed cooling apparatus 80 is depicted in FIG. 7. One of the plenums 83 of the housing 82 is depicted as bound by the bottom surface 87, a front wall 88, and a rear wall 89 of the apparatus 82. The front wall 88 and the rear wall 89 each form a pair of upper platforms 91, 92 and a pair of lower platforms 93, 94. These platforms 91, 92, 93, 94 are preferably formed from the same material as the walls 88, 89, and not merely adhered to the walls 88, 89. Of course, this is not a required feature of the multiple actuator distributed cooling apparatus 80. In addition, a top wall 95 (depicted in FIG. 8) may be installed on the device 80 in order to seal the plenums 83.

FIG. 8 shows the device of FIG. 7 after having two actuators 96, 97 positioned in the plenum 83 and a top wall 95 installed over the plenum 83. As depicted in the figure, a first actuator 96 rests on the upper platforms 91, 92 and a second actuator 97 rests on the lower platforms 93, 94. These two actuators 96, 97 preferably comprise a flexible diaphragm 98, 99 having a piezoelectric actuator 101, 102 mounted to the flexible diaphragm 98, 99. The preferred actuator 96, 97 is the elastomeric or polymeric actuator described above with regard to the exemplary embodiment 40. See FIG. 2. Other actuators could be used with the apparatus 80 described herein. However, the elastomeric/polymeric actuators are preferred for their low profile design, robust actuation, and inexpensive cost.

Power and control is supplied to the actuators 96, 97 by electrical wiring (not depicted). These wires typically enter the housing 82 through four small channels 103a, 103b, 103c (only three are depicted in FIG. 6) cut into both the upper and lower side walls 85, 86 of the housing 82. In fact, it is anticipated that the entire control electronics (not depicted) can be positioned in these channels 103a, 103b, 103c. Then, only power will preferably be supplied to these channels 103a, 103b, 103c and the control hardware they contain.

The actuators 96, 97 are preferably secured to the platforms 91, 92, 93, 94 in the apparatus housing 82. This is preferably accomplished by using a type of adhesive. As the material of the diaphragm 98, 99 is preferred to be an elastomer or polymer, and the preferred material of the housing 82 is a plastic, one of ordinary skill in the art will readily be able to select an appropriate adhesive, or other attachment mechanism.

Once the actuators 96, 97 are secured in the internal portion of the apparatus housing 82, the apparatus plenums 83 are essentially divided into three parts. The positioning of the actuators 96, 97 forms three separate chambers that generate three separate, but related, synthetic jet actuators. A first, or bottom, chamber 105 is bounded by the housing bottom wall 87, the housing front wall 88, the housing back wall 89, and the second actuator 97. The second chamber 106 is bounded by the first actuator 96, the front wall 88, the back wall 89, and the second actuator 97. The third, or top, chamber 107 is bounded by the first actuator 96, the front wall 88, the back wall 89, and the top wall 95.

Recall that the above implementation of a distributed cooling apparatus 60 (FIG. 4A) had a single orifice 46 leading from a chamber 45 to a single tube 61. However, in the present exemplary embodiment 80, each chamber 105, 106, 107 has one or more orifices 108. In the exemplary embodiment 80, each chamber 105, 106, 107 has two orifices fashioned into the front wall 88 of the apparatus housing 82. Each orifice is further fluidically connected to one of the tubes 81 emerging from the front wall 88 of the housing 82. Of course, it is not necessary that each chamber 105, 106, 107 have two orifices 108 and tubes 81. The present exemplary embodiment 80 will also work if there are more or less than two orifices 108 and tubes 81, or if there are different numbers for each chamber 105, 106, 107.

The tubes 81 are preferably attached to the housing 82 in generally the same horizontal plane, as depicted in FIG. 6. For this reason, FIGS. 7 and 8 appear to only show one tube 81 (and one orifice 108) attached to the housing 82 at approximately a mid-point of the housing front wall 88. The tubes 81 comprise an attachment end 109, attached to the housing front wall 88, and a fluid exit end 110, fluidically connecting a tube interior 111 to an ambient fluid 112.

Because the tubes 81 are preferably all attached to the housing 82 in the same horizontal plane, and the chambers 105, 106, 107 are not in the same horizontal plane, contoured passageways 113 are preferably used to fluidically connect each chamber 105, 106, 107 to the orifices 108 and tubes 81 served by that particular synthetic jet actuator.

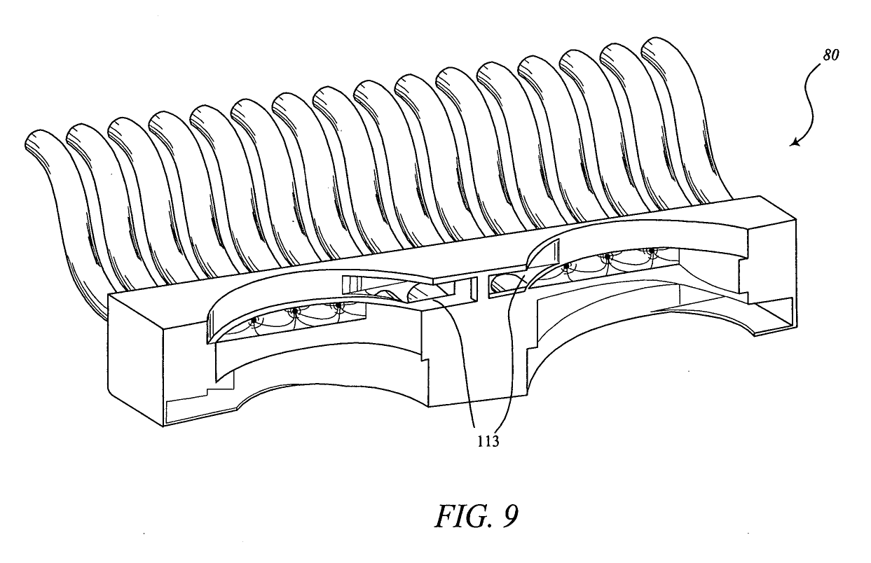

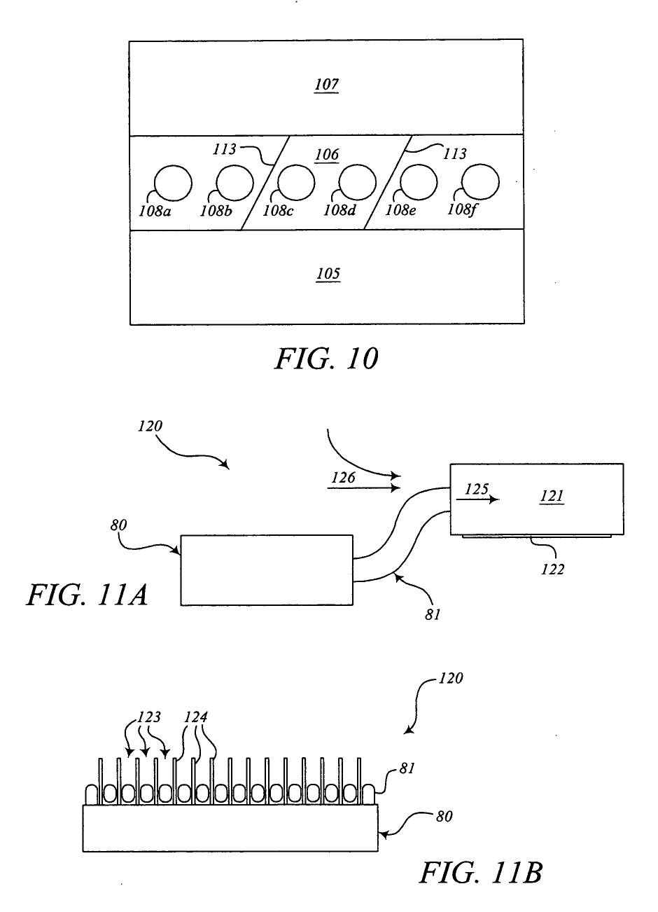

These ported passageways 113 are depicted in the cut-away sectional view of FIG. 9. Furthermore, FIG. 10 depicts a cut-away view of the three chambers 105, 106, 107 and the orifices 108a-f each chamber 105, 106, 107 services. By way of example, in FIG. 10, the first chamber 105 has two orifices 108e, 108f; the second chamber 106 has two orifices 108c, 108d; and the third chamber 107 has two orifices 108a, 108b. As can also be seen from FIGS. 9 and 10, the three chambers 105, 106, 107 in the housing 82 are not necessarily rectangular in cross-section, but rather, are oddly-shaped so as to direct fluid to the various tubes 81 serviced by each chamber 105, 106, 107.

Of course, in an alternative embodiment, the tubes 81 are not necessarily attached to the housing 82 in the same horizontal plane. For example, the tubes 81 to be serviced by each chamber 105, 106, 107 could be directly connected to the chamber 105, 106, 107. Then, the chambers 105, 106, 107 could be fashioned such that they have generally-rectangular cross-sections.

The operation of the exemplary multiple actuator distributed cooling apparatus 80 will now be described, with specific discussion of one of the “plenums” 83. It should be understood that the operation of the other “plenum” 83 will be similar. In operation, the two diaphragms 98, 99 are caused to oscillate in time-harmonic motion by the control systems (not depicted) controlling each piezoelectric actuator 101, 102 on each diaphragm 98, 99. The diaphragms 98, 99 are preferably actuated such that the two diaphragms 98, 99 oscillate out of phase with one-another.

As the two actuators 96, 97 move toward one-another, the volume of the second chamber 106 is reduced, and the volumes of the top chamber 107 and bottom chamber 105 are increased. Therefore, the second chamber 106 pushes fluid from the chamber 106 into the interior 111 of the tubes 81 connected to this chamber 106. Recall from the discussion relative to the single actuator exemplary embodiment 60 above, this pushing of fluid into the tube interior 111 acts like a “virtual piston” of fluid. See the description relating to FIGS. 4B and 4C above for an explanation of this process. This virtual piston moves into the interior 111 of the tubes 81, compressing the fluid in the tube interior 111, and thus causing a synthetic jet stream of fluid 115 to form at the exit end 110 of the tubes 81 connected to this second chamber 106.

The top chamber 107 and bottom chamber 105 undergo the opposite effect. Specifically, as the two diaphragms 98, 99 move toward one-another, both the top and bottom chambers 107, 105 pull fluid in from the interior 111 of the tubes 81 connected to these chambers 107, 105. This moves the “virtual piston” of fluid into the top and bottom chambers 107, 105, thereby causing the exit end 110 of the tubes 81 connected to these chambers 107, 105 to draw fluid in from the ambient 112.

As the diaphragms 98, 99 oscillate away from one-another, the second chamber's volume increases and fluid is pulled into the tubes 81 connected to this chamber 106 from the ambient 112. Of course, the volumes of the top and bottom chambers 107, 105 are similarly reduced. This causes a synthetic jet stream 115 of fluid to form at the exit ends 110 of the tubes 81 connected to these two chambers 107, 105.

As will be recognized by one of ordinary skill in the art, the principle of operation of the multiple actuator distributed cooling apparatus 80 is very similar to the operation of the basic distributed cooling apparatus 60 described above. For example, the tubes 81 of this embodiment 80 act as Helmholtz resonators in the manner described above with regard to the single actuator distributed cooling apparatus 60.

One common implementation 120 of a multiple actuator distributed cooling apparatus 80 is depicted in FIGS. 11A and 11B. Of course, many other implementations are possible for the apparatus 80, depending on the thermal management requirements of a system and the configuration of the apparatus 80. This exemplary implementation 120 is not limiting on the range of implementations for the apparatus 80. An exemplary implementation is presented merely to better illustrate the features of the present embodiment 80.

The exemplary implementation 120 involves the use of an extruded heat sink 121 for transporting heat away from a heated object 122. The multiple actuator distributed cooling apparatus 80 is positioned such that each of the tubes 81 in the apparatus 80 are aligned with a series of channels 123 formed with a series of fins 124 of the heat sink 121 such that the flow 125 of the jet passes through the channels 123 between the fins 124. This jet flow 125, in turn entrains secondary cool airflow 126 that is forced into the channels 123 of the heat sink 121.

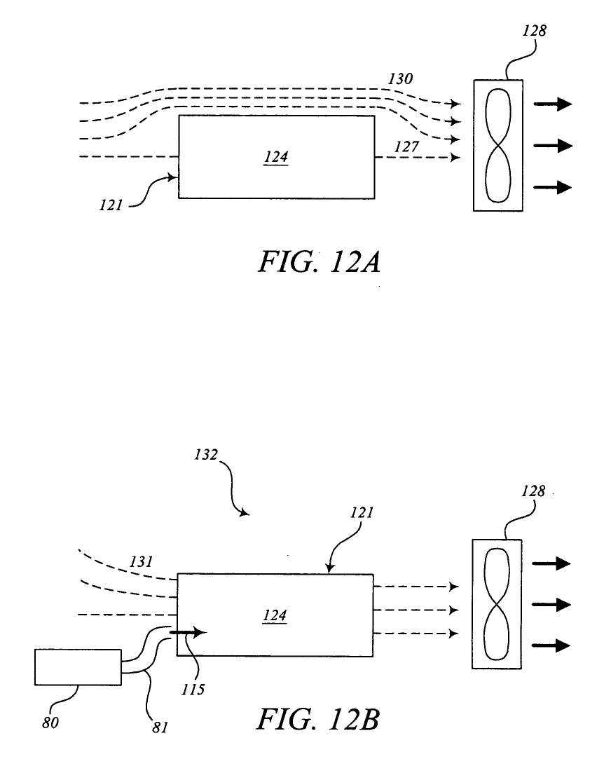

In another utilization 132 of this cooling module 80 the synthetic jet array of tubes 81 is used to reduce a flow bypass 130 in a heat sink 121 cooled by a fan-driven flow 127. FIG. 12A depicts the situation without a synthetic jet actuator 80. In this embodiment, the fan 128 draws fluid flow 127 though the channels 123 between the fins 124 of a heat sink 121. However, due to the pressure drop generated by the channels 123 of the heat sink 121 a large portion of the airflow 130 bypasses the heat sink 121. This is a common problem encountered in several applications like blade servers, telecom racks and the like, where the spacing between the component boards is narrow and there are large banks of fans attempting to drive massive airflow through the heat sink mounted on the hot components.

In this implementation, as depicted in FIG. 12B, a synthetic jet actuator is positioned such that the tubes 81 of the actuator 80 are directed to empty their flow 115 into the channels 123 of the heat sink 121. Note that because of the distributed nature of the apparatus 80, the actuator can be positioned below the plane of the heat sink 121, thereby preventing any interference with the flow. When the actuator 80 is caused to operate, a tangential synthetic jet 115 is directed near the left edge of the heat sink 121. The fan 128 continues to operate. The low-pressure, high momentum synthetic jet enables a significant entrainment 131 of the airflow 130 that was previously bypassing the heat sink 121.

It should be emphasized that the above-described embodiments of the present invention, particularly, any “preferred” embodiments, are merely possible examples of implementations, merely set forth for a clear understanding of the principles of the invention. Many variations and modifications may be made to the above-described embodiment(s) of the invention without departing substantially from the spirit and principles of the invention. All such modifications and variations are intended to be included herein within the scope of this disclosure and the present invention and protected by the following claims.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. A method for operating a synthetic jet ejector, comprising:
providing a synthetic jet ejector having first and second diaphragms; and
oscillating the first and second diaphragms out-of-phase with one another.

42. The method of claim 41, wherein the first and second diaphragms are equipped with first and second piezoelectric actuators, respectively.

43. The device of claim 41, wherein said first and second piezoelectric actuators are adhered to said first and second diaphragms.

44. The method of claim 43, wherein the first actuator causes the first diaphragm to oscillate by vibrating at a first frequency, wherein the second actuator causes the second diaphragm to oscillate by vibrating at a second frequency, and wherein at least one of the first and second frequencies are less than 200 Hz.

45. The method of claim 44, wherein both of the first and second frequencies are less than 200 Hz.

46. The method of claim 44, wherein the first frequency is the resonance frequency of the first diaphragm.

47. The method of claim 46, wherein the second frequency is the resonance frequency of the second diaphragm.

48. The method of claim 42, wherein the first actuator causes the first diaphragm to oscillate in time-harmonic motion.

49. The method of claim 41, wherein said first and second diaphragms are flexible diaphragms.

50. The method of claim 49, wherein the first and second diaphragms are disposed within a housing, and wherein each of the first and second diaphragms forms a portion of the housing.

51. The method of claim 41, wherein the first and second diaphragms comprise an elastomer material.

52. The method of claim 41, wherein the first and second diaphragms comprise a polymeric material.

53. The method of claim 41, wherein the synthetic jet ejector further comprises a housing having an interior which is divided into first and second chambers, wherein the first diaphragm is disposed within the first chamber, and wherein the second diaphragm is disposed within the second chamber.

54. The method of claim 53, wherein the housing has a plurality of apertures therein, and wherein the plurality of apertures are disposed in a coplanar arrangement.

55. The method of claim 53, wherein the housing has a first plurality of apertures therein which are in open communication with the first chamber, and a second plurality of apertures therein which are in open communication with the second chamber.

56. The method of claim 55, wherein the first plurality of apertures are disposed in a coplanar arrangement.

57. The method of claim 56, wherein the second plurality of apertures are also disposed in a coplanar arrangement.

58. The method of claim 41, wherein the synthetic jet ejector further comprises (a) a housing with an orifice therein, and (b) a tube having a proximal end and a distal end connected to an external surface of the housing, the proximal end of the tube enclosing at least a portion of the orifice;
wherein an operation of the synthetic jet ejector generates a synthetic jet stream at the distal end of the tube.

59. The method of claim 58, wherein the tube is adapted such that a Helmholtz-type resonance is created in an interior of the tube by the operation of the synthetic jet ejector.

60. The method of claim 53, wherein the open end of the tube is positioned adjacent to a heat sink comprising a plurality of fins, and wherein the synthetic jet stream passes between two of the plurality of fins.

61. The method of claim 41, wherein the first and second diaphragms are arranged in parallel.
